(19) United States
(12) Patent Application Publication
(10) Pub. No.: US 2022/0052462 A1
(43) Pub. Date: Feb. 17, 2022

(54) THREE-DIMENSIONAL MOUNTING STRUCTURE AND METHOD FOR MOUNTING THE SAME

(71) Applicant: TRIPLE WIN TECHNOLOGY(SHENZHEN) CO.LTD., Shenzhen (CN)

(72) Inventor: WENG-JING LIU, Shenzhen (CN)

(21) Appl. No.: 17/402,740

(22) Filed: Aug. 16, 2021

(30) Foreign Application Priority Data
Aug. 17, 2020 (CN) 202010827171.7

(51) Int. Cl. H01R 4/04

(52) U.S. Cl. CPC H01R 4/04

(57) ABSTRACT

A three-dimensional mounting structure includes a first mounting component, a second mounting component facing the first mounting component, a connecting layer disposed between the first mounting component and the second mounting component, a third mounting component, an adhesive layer, and a barrier sheet. The first mounting component includes a first end surface. The third mounting component is bonded on the first end surface through the adhesive layer. The connecting layer includes a second end surface close to the first end surface. The three-dimensional mounting structure can avoid the adhesive layer overflowing from the first end surface to the second end surface and improve the electronic product yield. A method for assembling the three-dimensional mounting structure is also disclosed.

### FIELD

The subject matter relates to manufacturing, and more particularly, to a three-dimensional mounting structure and a method for mounting the three-dimensional mounting structure.

### BACKGROUND

Different components in an electronic product may require to be bonded together by glue. A gap may appear after the different components are bonded together. The glue may overflow into the gap, causing the glue between the different components to be insufficient, thus resulting in poor appearance and functionality of the electronic product. Especially when the components need to be electrically connected through conductive glue, short circuit or open circuit of the electronic product may happen. Therefore, there is room for improvement in the art.

### BRIEF DESCRIPTION OF THE DRAWINGS

Implementations of the present technology will now be described, by way of example only, with reference to the attached figures.

FIG. 1 is a front elevation view of an embodiment of a three-dimensional mounting structure according to the present disclosure.

FIG. 2 is a cross-sectional view taken along II-II of FIG. 1.

FIG. 3 is a diagrammatic view of an embodiment of a barrier sheet according to the present disclosure.

FIG. 4 is a diagrammatic view of another embodiment of a barrier sheet according to the present disclosure.

FIG. 5 is a diagrammatic view of an embodiment of a first mounting component mounted with a second mounting component through an adhesive layer according to the present disclosure.

FIG. 6 is a diagrammatic view of an embodiment of arranging a plurality of adhesive points and an adhesive strip on the first mounting component and the second mounting component in FIG. 5.

FIG. 7 is a flowchart of a method for assembling a three-dimensional mounting structure according to the present disclosure.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

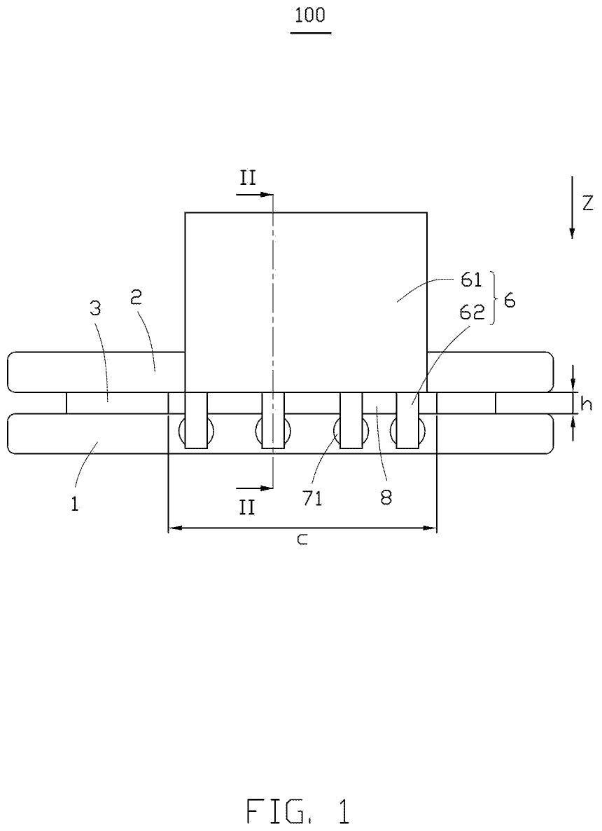

FIGS. 1 to 3, and 5 illustrate an embodiment of a three-dimensional mounting structure 100, which includes a first mounting component 1 and a second mounting component 2. The first mounting component 1 and the second mounting component 2 which correspondingly arranged are connected to each other through a connecting layer 3. The first mounting component 1 includes a first end surface 4. The three-dimensional mounting structure 100 further includes a third mounting component 6. The third mounting component 6 is bonded on the first end surface 4 through an adhesive layer 7. The connecting layer 3 includes a second end surface 5 close to the first end surface 4. A barrier sheet 8 is disposed on the second end surface 5 corresponding to the third mounting component 6. The three-dimensional mounting structure 100 realizes the three-dimensional mounting by setting the adhesive layer 7 on the first end surface 4 to make the third mounting component 6 perpendicular to the first mounting component 1 and the second mounting component 2.

The first mounting component 1 and the second mounting component 2 have dimensional tolerance and cannot match with each other completely, which results to a gap between edges of the first mounting component 1 and the second mounting component 2 after bonded together. That is, there will be a height difference between the second end surface 5 and the first end surface 4. Bonded a barrier sheet (barrier sheet 8) on the second end surface 5 can fill the gap and prevent the adhesive layer 7 from overflowing into the gap, resulting to improve the appearance and functionality of an electronic product.

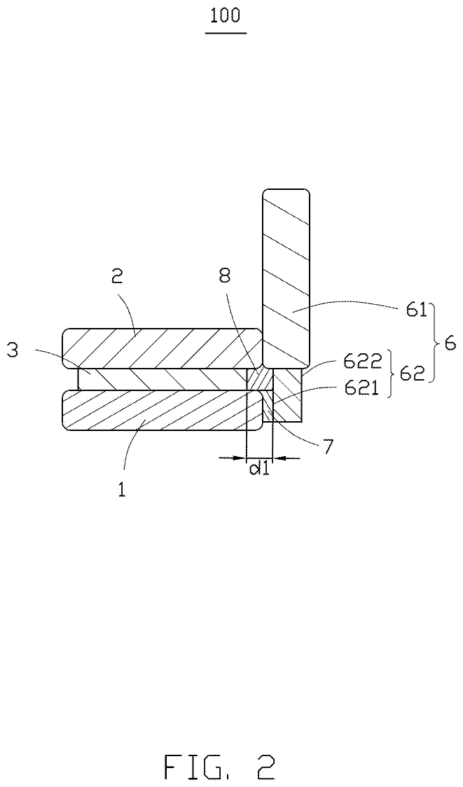

Referring to FIGS. 1 and 2, after the first mounting component 1 and the second mounting component 2 are laminated and bonded together, the third mounting component 6 is vertically bonded on one end of the first mounting component 1. And the third mounting component 6 extends from the first mounting component 1 to the second mounting component 2.

Referring to FIGS. 1 and 2, the third mounting component 6 includes a mounting body 61 and a plurality of mounting portions 62 connected to an end of the mounting body 61. The adhesive layer 7 includes a plurality of connecting units 71 corresponding to the mounting portions 62 one by one. Each of the mounting portions 62 includes a first surface 621 and a second surface 622 opposite to the first surface 621. The connecting units 71 disposed between the first surface 621 and the first end surface 4.

In an embodiment, the third mounting component 6 includes, but is not limited to, a flexible printed circuit (FPC). The mounting portions 62 are golden fingers of the FPC. The golden fingers are electrically connected with other components during the mounting process, so the adhesive layer 7 may be conductive adhesive. A plurality of adhesive points 10 are pointed on the first end surface 4. Then the mounting portions 62 of the third mounting component 6 are mounted on the adhesive points 10. The third mounting component 6 is perpendicular to the first mounting component 1 and the second mounting component 2. After bonding, the mounting portions 62 flatten the adhesive points 10 to form the connecting units 71.

If the adhesive layer 7 spreads from the first end surface 4 to the second end surface 5, and creeps along the second end surface 5, a connecting line between the connecting units 71 in the vertical direction may be formed, resulting in poor appearance and functionality of the electronic product. In order to prevent the adhesive layer 7 from spreading from the first end surface 4 to the second end surface 5, and creeping along the second end surface 5, the barrier sheet 8 is positioned on the second end surface 5 corresponding to the third mounting component 6. The barrier sheet 8 can prevent the adhesive layer 7 from spreading from the first end surface 4 to the second end surface 5 and fill the gap between the first end surface 4 and the second end surface 5.

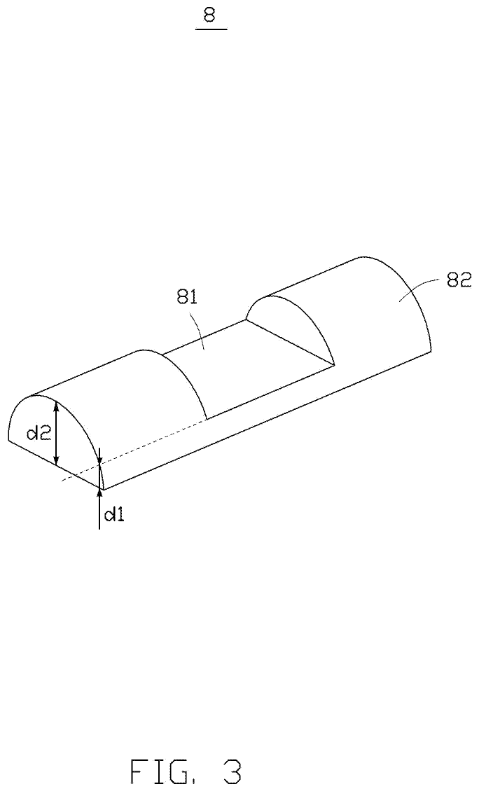

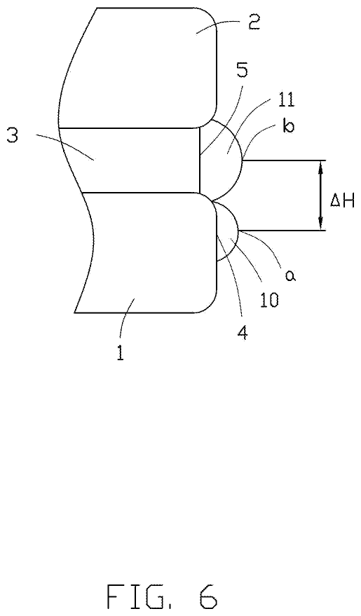

In an embodiment, referring to FIG. 3, the barrier sheet 8 includes a plurality of connecting portions 81 and a plurality of barrier portions 82. Each of the plurality of connecting portions 81 is positioned between adjacent two of the barrier portions 82. Each of the mounting portions 62 is positioned on each of the connecting portions 81, respectively. Referring to FIG. 6, the barrier sheet 8 is formed through an adhesive strip 11. The adhesive strip 11 is formed during the bonding process. The adhesive strip 11 has a semi cylindrical structure. Parts of the adhesive strip 11 are flatten by the mounting portions 62 of the third mounting component 6 to form the connecting portions 81. Other parts of the adhesive strip 11 are not flatten by the mounting portions 62 to form the barrier portions 82.

Referring to FIGS. 1 and 3, the first mounting component 1 and the second mounting component 2 are connected to each other through the connecting layer 3. The connecting layer 3 is first bonded on the first mounting component 1, and then the second mounting component 2 is bonded on the connecting layer 3 along a direction “Z” perpendicular to the first mounting component 1. The first mounting component 1 and the second mounting component 2 have dimensional tolerance and cannot match with each other completely, which results to a gap between edges of the first mounting component 1 and the second mounting component 2 after bonded together. A size of the gap is related to the thickness of connecting layer 3. In an embodiment, along a direction “Z” perpendicular to the first mounting component of a major plane of the barrier sheet 8, a width “h” of the barrier sheet 8 is smaller than or equal to a thickness of the adhesive layer 7. Along a direction parallel to the first mounting component of a major plane of the barrier sheet, a length “c” of the barrier sheet 8 is longer than or equal to a length of the adhesive layer 7. In other word, the length “c” of the barrier sheet 8 is longer than or equal to a mounting size of the third mounting component 6. The length “c” is defined as a size extending along a surface parallel to the second end surface 5, and the length “c” is also perpendicular to the direction “Z”. The mounting size is a size of an overlapping size of the mounting portion 62 bonded on the first end surface 4.

In an embodiment, referring to FIGS. 1, 2, and 3, a first thickness “d1” of the barrier sheet 8 is equal to a distance between the second end surface 5 and the first surface 621. A second thickness “d2” of the each of the barrier portions 82 is larger than or equal to a distance between the second end surface 5 and the first surface 621, and smaller than or equal to a distance between the second end surface 5 and the second surface 622. It can be understood that, in order to better block and isolate the adhesive layer 7 from spreading from the first end surface 4 to the second end surface 5, a vertex of the barrier portion 82 is not lower than the first surface 621, but also not higher than the second surface 622.

In an embodiment, a material of the barrier sheet 8 is not limited to insulating adhesive. The insulating adhesive is arranged on the second end surface 5 by coating to form the barrier sheet 8.

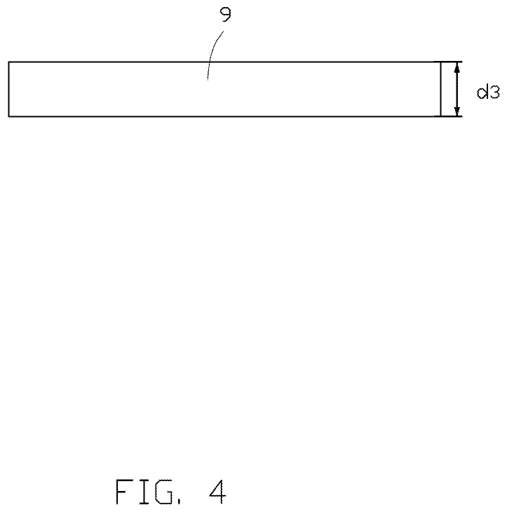

In another embodiment, referring to FIGS. 1 and 4, the barrier sheet (barrier sheet 9) has a rectangular structure. The barrier sheet 9 is designed according to a size of the dimensional tolerance between the first mounting component 1 and the second mounting component 2, and a size of the gap formed by the first mounting component 1 and the second mounting component 2. The barrier sheet 9 can prevent the adhesive layer 7 from spreading from the first end surface 4 to the second end surface 5 and fill the gap between the first end surface 4 and the second end surface 5. In an embodiment, along a direction “Z” perpendicular to the first mounting component of a major plane of the barrier sheet 9, a width of the barrier sheet 9 is smaller than or equal to the thickness of the adhesive layer 7. Along a direction parallel to the first mounting component of a major plane of the barrier sheet 9, the length of the barrier sheet 9 is longer than or equal to the length of the adhesive layer 7. In other word, the length of the barrier sheet 9 is longer than or equal to the mounting size of the third mounting component 6. The length is defined as a size extending along the surface parallel to the second end surface 5, and the length is also perpendicular to the direction “Z”. The mounting size is a size of an overlapping size of the mounting portion 62 bonded on the first end surface 4. A third thickness “d3” of the barrier sheet 9 is equal to the distance between the second end surface 5 and the first surface 621, resulting to better block and isolate the adhesive layer 7 from spreading from the first end surface 4 to the second end surface 5.

In an embodiment, the barrier sheet 9 is not limited to be made of an insulating adhesive. The insulating adhesive is arranged on the second end surface 5 by coating to form the barrier sheet 9. The barrier sheet 9 can improve the mounting stability of the third mounting component 6. It can be understood that the barrier sheet 9 can also be other insulating materials, which are pasted on the second end surface 5 through adhesive.

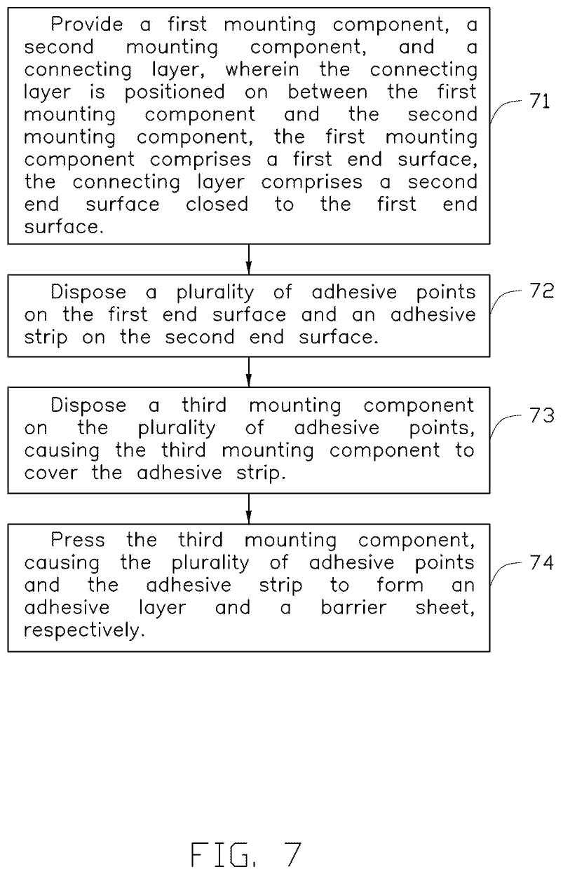

FIG. 7 illustrates a flowchart of a method for assembling the three-dimensional mounting structure 100 according to an embodiment. The method for assembling the three-dimensional mounting structure 100 is provided by way of example, as there are a variety of ways to carry out the method. The method can begin at block 71.

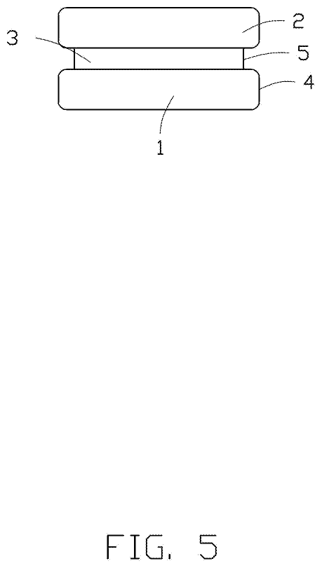

Block 71, referring to FIG. 5, the first mounting component 1, the second mounting component 2, and the connecting layer 3 are provided. The connecting layer 3 is positioned between the first mounting component 1 and the second mounting component 2. The first mounting component 1 includes the first end surface 4. The connecting layer 3 includes the second end surface 5 close to the first end surface 4.

Block 72, referring to FIG. 6, the adhesive points 10 are disposed on the first end surface 4. The adhesive strip 11 is formed on the second end surface 5.

Block 73, referring to FIG. 1, the third mounting component 6 is disposed on the adhesive points 10, causing the third mounting component 6 to cover the adhesive strip 11.

Block 74, referring to FIG. 1, the third mounting component 6 is pressed on the adhesive points 10 to make the adhesive points 10 form the adhesive layer 7. The third mounting component 6 is connected to the first end surface 4 through the adhesive layer 7. During the pressing process, the adhesive strip 11 forms the barrier sheet 8. So, the three-dimensional mounting structure 100 is obtained.

In an embodiment, referring to FIG. 6, each of the adhesive points 10 has a hemispherical structure. The adhesive strip 11 has a semi cylindrical structure. During the coating process, the adhesive points 10 are directly coated on the first end surface 4 through a professional dispensing equipment. The adhesive strip 11 is directly coated on the second end surface 5 through a professional adhesive coating equipment.

In an embodiment, referring to FIG. 6, each of the adhesive points 10 includes a first acme “a”. The adhesive strip 11 includes a second acme “b”. A height of the second acme “b” is higher than a height of the first acme “a”, results to better fill the gab and isolate the adhesive points 10 spreading from the first end surface 4 to the second end surface 5. The third mounting component 6 is attached to the adhesive strip 11, and the adhesive strip 11 is flattened to form a wider contact area with the third mounting component 6, thereby improving the adhesion stability of the third by the mounting component 6 on the adhesive strip 11.

In an embodiment, along the direction “Z”, a distance “ΔH” between the first acme “a” and the second acme “b” is larger than or equal to a distance between the first acme “a” and the first end surface 4. This can avoid the adhesive of the adhesive points 10 overflow to an outside of the third mounting component 6 during flattening process.

The smaller of the surface tension of the adhesive, the better of the wettability and leveling property of the adhesive. The surface tension of the adhesive should not be too small, otherwise it is easy to overflow. However, the surface tension of the adhesive should not be too large, otherwise the viscosity of the adhesive will drop. So, the surface tension of the adhesive needs to be within a reasonable range.

In an embodiment, in order to avoid the adhesive creeping and overflowing from the first end surface 4 to the second end surface 5 and two adjacent adhesive points 10 connect into a line, the adhesive of the adhesive point 10, it is necessary to control the surface tension of the adhesive at a higher level. At the same time, in order to ensure the adhesion stability of the third mounting component 6, the adhesive strip 11 needs to have good adhesion. So, it is necessary to control the surface tension of the adhesive of the adhesive strip 11 at a slightly lower level.

The three-dimensional mounting structure 100 has the following advantages:

1. The three-dimensional mounting structure 100 can improve the yield of the electronic product.

2. The shapes and the amounts of the adhesive of the adhesive layer 7 and barrier sheet 8 can be controlled according to different electronic products, thereby improving the appearance and functionality of the electronic product.

3. The barrier sheet 8 can also fill the gap between the first mounting component 1 and the second mounting component 2, thereby preventing the adhesive layer 7 from overflowing into the gap.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure, up to and including, the full extent established by the broad general meaning of the terms used in the claims.

What is claimed is:

1. A three-dimensional mounting structure, comprising:
a first mounting component;
a second mounting component;
a connecting layer disposed between the first mounting component and the second mounting component;
a third mounting component;
an adhesive layer; and
a barrier sheet,
wherein, the first mounting component comprises a first end surface, the third mounting component is bonded on the first end surface through the adhesive layer, the connecting layer comprises a second end surface close to the first end surface, the barrier sheet is disposed between the second end surface and the third mounting component.

2. The three-dimensional mounting structure of claim 1, wherein the third mounting component comprises a mounting body and a plurality of mounting portions connected to an end of the mounting body, each of the plurality of mounting portions comprises a first surface and a second surface opposite to the first surface,
the adhesive layer comprises a plurality of connecting units each corresponding to the plurality of mounting portions, each of the plurality of connecting units is disposed between the first surface and the second surface.

3. The three-dimensional mounting structure of claim 2, wherein along a direction perpendicular to the first mounting component of a major plane of the barrier sheet, a width of the barrier sheet is smaller than or equal to a thickness of the adhesive layer;
along a direction parallel to the first mounting component of a major plane of the barrier sheet, a length of the barrier sheet is longer than or equal to a length of the adhesive layer.

4. The three-dimensional mounting structure of claim 3, wherein the barrier sheet comprises a plurality of connecting portions and a plurality of barrier portions, each of the plurality of connecting portions is positioned between adjacent two of the plurality of barrier portions,
the plurality of mounting portions is positioned on the plurality of connecting portions.

5. The three-dimensional mounting structure of claim 4, wherein a first thickness of the barrier sheet is equal to a distance between the second end surface and the first surface,
a second thickness of each of the plurality of barrier portions is larger than or equal to the distance between the second end surface and the first surface, and is smaller than or equal to a distance between the second end surface and the second surface.

6. The three-dimensional mounting structure of claim 3, wherein the barrier sheet is a cuboid.

7. The three-dimensional mounting structure of claim 6, wherein a third thickness of the barrier sheet is equal to a distance between the second end surface and the first surface.

8. The three-dimensional mounting structure of claim 1, wherein the barrier sheet is made of an insulating adhesive.

9. The three-dimensional mounting structure of claim 1, wherein the adhesive layer is made of a conductive adhesive.

10. A method for assembling a three-dimensional mounting structure, comprising:
providing a first mounting component, a second mounting component, and a connecting layer, wherein the connecting layer is positioned between the first mounting component and the second mounting component, the first mounting component comprises a first end surface, the connecting layer comprises a second end surface close to the first end surface;
disposing a plurality of adhesive points on the first end surface and an adhesive strip on the second end surface;
disposing a third mounting component on the plurality of adhesive points, causing the third mounting component to cover the adhesive strip; and
pressing the third mounting component, causing the plurality of adhesive points and the adhesive strip to form an adhesive layer and a barrier sheet, respectively.

11. The method of claim 10, wherein each of the plurality of adhesive points has a hemispherical structure, and the adhesive strip has a semi cylindrical structure.

12. The method of claim 11, wherein each of the plurality of adhesive points comprises a first acme, the adhesive strip comprises a second acme, a height of the second acme is higher than a height of the first acme.

13. The method of claim 10, wherein the third mounting component comprises a mounting body and a plurality of mounting portions connected to an end of the mounting body, each of the plurality of mounting portions comprises a first surface and a second surface opposite to the first surface,
the adhesive layer comprises a plurality of connecting units each corresponding to the plurality of mounting portions, each of the plurality of connecting units is disposed between the first surface and the second surface.

14. The method of claim 13, wherein along a direction perpendicular to the first mounting component of a major plane of the barrier sheet, a width of the barrier sheet is smaller than or equal to a thickness of the adhesive layer,
along a direction parallel to the first mounting component of a major plane of the barrier sheet, a length of the barrier sheet is longer than or equal to the length of the adhesive layer.

15. The method of claim 14, wherein the barrier sheet comprises a plurality of connecting portions and a plurality of barrier portions, each of the plurality of connecting portions is positioned between adjacent two of the plurality of barrier portions,
the plurality of mounting portions is positioned on the plurality of connecting portions.

16. The method of claim 15, wherein a first thickness of the barrier sheet is equal to a distance between the second end surface and the first surface,
a second thickness of each of the plurality of barrier portions is larger than or equal to the distance between the second end surface and the first surface, and is smaller than or equal to a distance between the second end surface and the second surface.

17. The method of claim 14, wherein the barrier sheet is a cuboid.

18. The method of claim 17, wherein a third thickness of the barrier sheet is equal to a distance between the second end surface and the first surface.

19. The method of claim 10, wherein the adhesive strip is made of an insulating adhesive.

20. The method of claim 10, wherein the adhesive point is made of a conductive adhesive.
